(19) United States
(12) Patent Application Publication
(10) Pub. No.: US 2011/0232742 A1
(43) Pub. Date: Sep. 29, 2011

(54) Systems and Methods for Preparing Components of Photovoltaic Cells

(76) Inventors: John C. Warner, Wilmington, MA (US); Helen Van Benschoten, Wakefield, MA (US); Amy Cannon, Wilmington, MA (US)

(21) Appl. No.: 13/030,031

(22) Filed: Feb. 17, 2011

Related U.S. Application Data
(60) Provisional application No. 61/305,861, filed on Feb. 18, 2010.
(60) Provisional application No. 61/305,899, filed on Feb. 18, 2010.
(60) Provisional application No. 61/305,908, filed on Feb. 18, 2010.
(60) Provisional application No. 61/305,911, filed on Feb. 18, 2010.

(51) Int. Cl. H01L 31/0224; H01L 51/44; H01L 31/18; H01B 1/02; B82Y 30/00; B82Y 40/00

(52) U.S. Cl. 136/256; 438/98; 252/501.1; 257/E31.124; 977/773; 977/840

(57) ABSTRACT

A method of making a metal oxide based component for use in a solar cell, without sintering the metal oxide. The method includes flocculating a metal oxide solution that is used to produce the non-sintered metal oxide component. A composition for use in making a non-sintered solar cell component. The composition includes a metal oxide solution and a flocculant for flocculating particles of the metal oxide solution. A solar cell having an anode and interfacing the anode is a semiconductor that includes a metal oxide that is produced by a method that does not require sintering of the metal oxide. The method comprises flocculating a solution of the metal oxide. The solar cell further includes a cathode and an electrolyte in electrical communication with the semiconductor and the cathode.

### CROSS-REFERENCE TO RELATED APPLICATIONS

This application claims priority to U.S. Provisional Application No. 61/305,861, filed Feb. 18, 2010 and entitled, “SEMICONDUCTOR ADDITIVES FOR ELECTRON CHANNELING” [WBI 24.004], U.S. Provisional Application No. 61/305,899, filed Feb. 18, 2010 and entitled, COMPOSITION OF MATTER FOR SOLAR CELLS [WBI 24.006], U.S. Provisional Application No. 61/305,908, filed Feb. 18, 2010 and entitled, “NANONODULARITY FOR SEMICONDUCTORS IN SOLAR CELLS” [WBI 24.007] and U.S. Provisional Application No. 61/305,911, filed Feb. 18, 2010 and entitled, ROOM TEMPERATURE COALESCENCE OF METAL OXIDES FOR SOLAR CELLS [WBI 24.008], the disclosures of which are hereby incorporated herein by reference.

Further, this application is related to Attorney Docket No. ONEP.P0024US entitled “ADDITIVES FOR SOLAR CELL SEMICONDUCTORS”, Attorney Docket No. ONEP.P0030US entitled “SEMICONDUCTOR COMPOSITIONS FOR DYE-SENSITIZED SOLAR CELLS”, all of which are filed concurrently herewith and the disclosures of which are hereby incorporated herein by reference.

### TECHNICAL FIELD

The current disclosure generally relates to photovoltaic cells. Specifically, the current disclosure relates to the preparation of components of photovoltaic cells.

### BACKGROUND OF THE INVENTION

The availability of affordable sources of energy is critical to the modern way of life. Activities concerning all types of businesses, manufacturing, transportation etc. require energy in one form or another. The primary source of energy in the United States and many other countries is fossil fuels such as, coal, oil and natural gas. Fossil fuels, however, are non-renewable sources of energy, i.e., energy sources that cannot be recreated by man. Furthermore, the burning of fossil fuels for energy produces carbon dioxide, which is a greenhouse gas. Excessive amounts of greenhouse gases cause unusual warming of the earth's atmosphere—the greenhouse effect, which is a significant environmental concern. What is more, the demand for energy worldwide is increasing. There is a need, therefore, for the development of sustainable and affordable renewable sources of energy that are environmentally friendly.

Solar energy is one of several energy sources that is increasingly being relied on to provide renewable clean energy. One aspect of solar technology includes the use of photovoltaic cells to convert sunlight to electricity. The photovoltaic cell absorbs some of the sunlight to which it is exposed and transfers the energy from this sunlight to electrons of atoms in a semiconductor material in the photovoltaic cell. The energy transferred to the electrons cause the electrons to move from their normal positions in the atoms. The movement of these electrons creates an electrical flow—current. There are different types of photovoltaic cells. Examples of photovoltaic cells are crystalline silicon solar cells and dye-sensitized solar cells (DSSCs).

One type of dye-sensitized solar cell is known as the Gratzel cell. Hamann et al., “Advancing beyond current generation dye-sensitized solar cells,” (the disclosure of which is incorporated in its entirety by reference, hereinafter “Hamann”) describes the Gratzel cell. The Gratzel cell includes crystalline titanium dioxide nanoparticles serving as a photoanode in the photovoltaic cell. The titanium dioxide is coated with light sensitive dyes. The titanium dioxide photoanode includes 10-20 nm diameter titanium dioxide particles forming a 12 μm transparent film. The 12 μm titanium dioxide film is made by sintering the 10-20 nm diameter titanium dioxide particles so that they have a high surface area. The titanium dioxide photoanode also includes a 4 μm film of titanium dioxide particles having a diameter of about 400 nm. The coated titanium dioxide films are located between two transparent conducting oxide (TCO) electrodes. Also disposed between the two TCO electrodes is an electrolyte with a redox shuttle.

The Gratzel cell may be made by first constructing a top portion. The top portion may be constructed by depositing fluorine-doped tin dioxide (SnO₂F) on a transparent plate, which is usually glass. A thin layer of titanium dioxide (TiO₂) is deposited on the transparent plate having a conductive coating. The TiO₂ coated plate is then dipped into a photosensitized dye such as ruthenium-polypyridine dye in solution. A thin layer of the dye covalently bonds to the surface of the titanium dioxide. A bottom portion of the Gratzel cell is made from a conductive plate coated with platinum metal. The top portion and the bottom portion are then joined and sealed. The electrolyte, such as iodide-triiodide, is then typically inserted between the top and bottom portions of the Gratzel cell.

In operation, the dye absorbs sunlight, which results in the dye molecules becoming excited and transmitting electrons into the titanium dioxide. The titanium dioxide accepts the energized electrons, which travel to a first TCO electrode. Concurrently, the second TCO electrode serves as a counter electrode, which uses a redox couple such as iodide-triiodide (I₃⁻/I⁻) to regenerate the dye. If the dye molecule is not reduced back to its original state, the oxidized dye molecule decomposes. As the dye-sensitized solar cell undergoes a large number of the oxidation-reduction cycles in the lifetime of operation, more and more dye molecules undergo decomposition over time, and the cell energy conversion efficiency decreases.

Furthermore, not all the energy of the sunlight to which the dye-sensitized solar cell is exposed is converted to electrical energy. Indeed, the maximum efficiency of the dye-sensitized solar cell has been found to be about 11%. The maximum efficiency is a function of the thickness of the titanium dioxide film, which in turn affects the cost of the dye-sensitized solar cell. There is a need, therefore, for increasing the efficiency and reducing the cost of dye-sensitized solar cells. One challenge in the fabrication of dye-sensitized solar cell is the creation of thin films having good conductivity; that is, the ability to effectively conduct photo-induced electrons to an electrode.

### BRIEF SUMMARY OF THE INVENTION

Embodiments of the present invention are directed to apparatus and methods for preparing components of a solar cell. A representative embodiment of the invention is directed to a method of making a component for use in a solar cell. The method comprises flocculating a metal oxide solution and processing the flocculated metal oxide solution to form a component for use in a solar cell, without sintering the metal oxide.

A further embodiment of the invention comprises forming an aqueous solution by a process that includes adding metal oxide nanoparticles having a relatively small mean crystal diameter, for example, in the range of 5-10 nm and aggregate dimension of 95-105 nm to a solvent. The process further includes adding fused metal oxide nanoparticles, for example, having a mean crystal diameter of 10-20 nm and agglomerate dimension of 425-475 nm clusters to the solvent. The method of making the component for the solar cell also includes agitating the aqueous solution and removing at least some of the solvent from the aqueous solution to produce a metal oxide film, without sintering the metal oxide film.

An additional representative embodiment of the invention includes a solar cell component having a metal oxide that is produced by a method that does not require sintering of the metal oxide. The method includes flocculating a solution of the metal oxide and processing the flocculated metal oxide solution to form the solar cell component.

A further representative embodiment of the invention is a non-sintered solar cell component that includes metal oxide nanoparticles having a mean crystal diameter of 5-10 nm and aggregate dimension of 95-105 nm. The non-sintered solar cell component further includes fused metal oxide nanoparticles having a mean crystal diameter of 10-20 nm and agglomerate dimension of 425-475 nm clusters.

A further embodiment of the invention is a composition for use in making a non-sintered solar cell component. The composition includes a metal oxide solution and a flocculant for flocculating particles of the metal oxide solution.

Another embodiment of the invention is a solar cell having an anode. Interfacing the anode is a semiconductor that includes a metal oxide and is produced by a method that does not require sintering of the metal oxide. The method includes flocculating a solution of the metal oxide and processing the flocculated metal oxide solution to form the semiconductor. The solar cell further includes a cathode and an electrolyte in electrical communication with the semiconductor and the cathode.

The foregoing has outlined rather broadly the features and technical advantages of the present invention in order that the detailed description of the invention that follows may be better understood. Additional features and advantages of the invention will be described hereinafter which form the subject of the claims of the invention. It should be appreciated by those skilled in the art that the conception and specific embodiment disclosed may be readily utilized as a basis for modifying or designing other structures for carrying out the same purposes of the present invention. It should also be realized by those skilled in the art that such equivalent constructions do not depart from the spirit and scope of the invention as set forth in the appended claims. The novel features which are believed to be characteristic of the invention, both as to its organization and method of operation, together with further objects and advantages will be better understood from the following description when considered in connection with the accompanying figures. It is to be expressly understood, however, that each of the figures is provided for the purpose of illustration and description only and is not intended as a definition of the limits of the present invention.

### BRIEF DESCRIPTION OF THE DRAWINGS

For a more complete understanding of the present invention, reference is now made to the following descriptions taken in conjunction with the accompanying drawings, in which:

FIGS. 1A, 1B and 1C are diagrams illustrating the effects of a prior art process that sinters titanium dioxide films;

FIG. 2 shows a process for preparing a titanium dioxide based dye-sensitized film according to one embodiment of the invention;

FIGS. 3A and 3B are diagrams illustrating the effect of preparing a titanium dioxide based dye-sensitized film according to one embodiment of the invention;

FIG. 4 is a schematic diagram of photovoltaic cell according to one embodiment of the invention;

FIGS. 5A-5D are graphs showing how characteristics of a titanium dioxide based dye-sensitized film vary according to the method of preparing the titanium dioxide based dye-sensitized film;

FIGS. 6A and 6B show solar panels according to one embodiment of the invention.

### DETAILED DESCRIPTION OF THE INVENTION

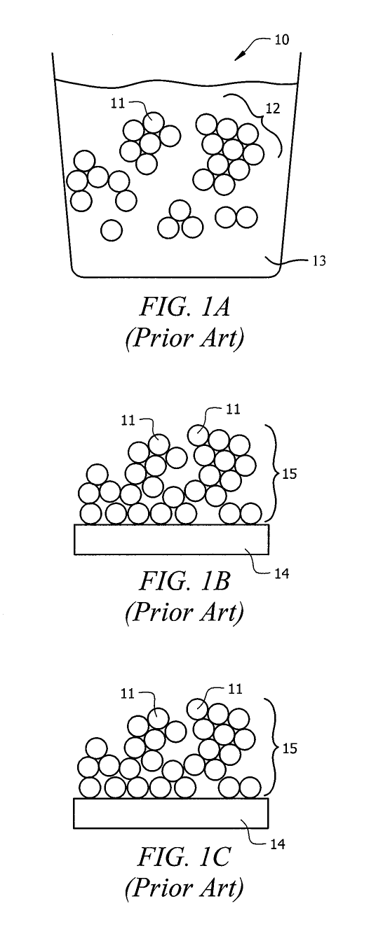

FIGS. 1A, 1B and 1C are diagrams illustrating the effects of a prior art process that sinters titanium dioxide used in a dye-sensitized solar cell. FIG. 1A shows the first step of the process where titanium dioxide particles 11 and their agglomerates 12 are dispersed in a solvent 13 to form a slurry solution 10. FIG. 1B shows the next step of the process where slurry 10 is deposited on anode 14 to form titanium dioxide film 15. Anode 14 may be materials such as indium tin oxide, fluorinated tin oxide and the like. FIG. 1B shows poor contact between particles 11. The electrical contact between the titanium dioxide particles and their agglomerates as well as the contact between the anode and the titanium dioxide is of paramount importance for the performance of the dye-sensitized solar cell. To achieve better contact of particles 11 with each other and with anode 14, titanium dioxide film 15 is sintered. Typically, the sintering of titanium dioxide films is carried out by exposing it to temperatures in the range of 300-500° C. A preferred temperature for sintering titanium dioxide films is 450° C. FIG. 1C shows sintered titanium dioxide film having good contact including good electrical contact between particles 11 as a result of the sintering process. The sintering process, however, is an impediment to successful commercialization of this particular dye-sensitized solar cell technology because it consumes a significant amount of energy and limits the anode material to materials that can withstand the high temperatures of sintering.

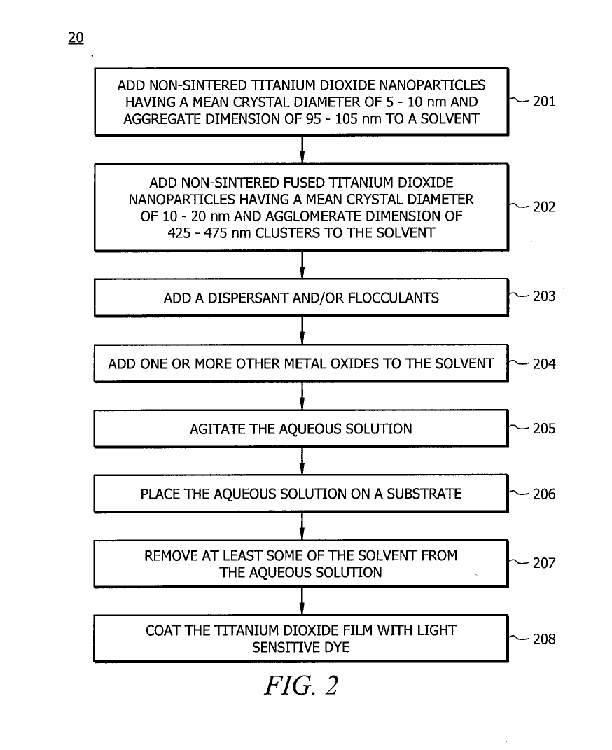

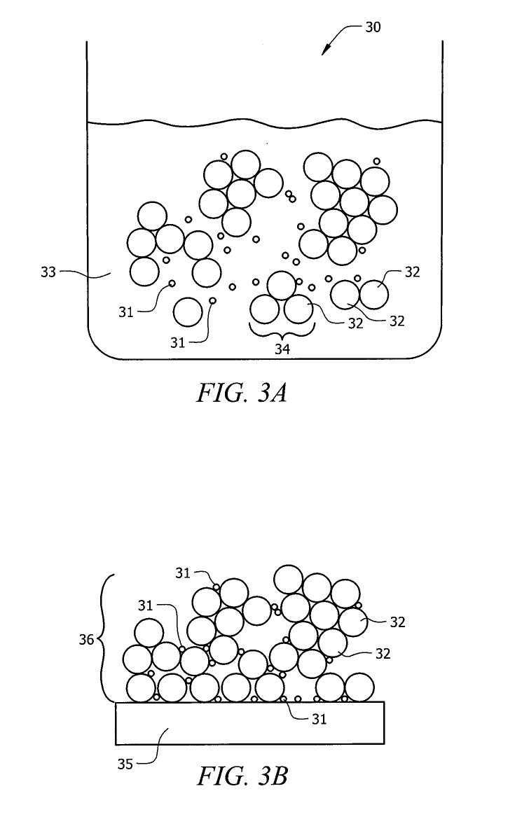

FIG. 2 shows process 20 for preparing a titanium dioxide based dye-sensitized film according to one embodiment of the invention. The steps of process 20 will be discussed below in conjunction with FIGS. 3A and 3B.

FIGS. 3A and 3B show the effect of process 20 in preparing a titanium dioxide film for a solar cell. Process 20 includes the preparation of a slurry solution 30 shown in FIG. 3A. Slurry solution 30 may be prepared, as shown in process 201, by adding titanium dioxide nanoparticles 31 (FIG. 3A) having a relatively small mean crystal diameter and aggregate dimension of about 20 times the mean crystal diameter to a solvent 33, such as water. In embodiments of the invention, titanium dioxide nanoparticles have a mean crystal diameter of about 5-10 nm and aggregate dimension of about 95-105 nm (titanium dioxide nanoparticle aggregate 31). Titanium dioxide nanoparticle aggregate 31 is formed because of mutual attractions between titanium dioxide nanoparticles with mean crystal diameter of about 5-10 nm. In one specific experiment, the mean crystal diameter was 5 nm and the aggregate dimension was 100 nm. Titanium dioxide nanoparticle aggregate 31 may be produced by a method involving the use of Trimesic acid. This method is disclosed in Cannon et al., “The Low Temperature Processing of Titanium Dioxide Films by the Addition of Trimesic Acid,” the disclosure of which is incorporated in its entirety by reference (hereinafter, “Cannon”). In embodiments of the invention, aqueous solution 30 includes about 5-15 wt % of titanium dioxide nanoparticles 31 after the composition for making the titanium dioxide film is completed.

Process 202 involves adding fused titanium dioxide nanoparticles 32 having a mean crystal diameter of 10-20 nm and agglomerate dimension of 425-475 nm clusters to the solvent. In embodiments of the invention, fused titanium dioxide nanoparticles may have a mean crystal diameter of about 20 nm (titanium dioxide nanoparticles 32) and agglomerate dimension of about 450 nm (titanium dioxide nanoparticle agglomerate 34). Titanium dioxide nanoparticles 32 fuse together to form titanium dioxide nanoparticle agglomerate 34 and may be produced by flame pyrolysis of titanium chloride (TiCl₄) and is commercially available from Degussa. In embodiments of the invention, aqueous solution 30 includes 20-50 wt % of titanium dioxide nanoparticles 32. For the purpose of the present embodiment of the invention, it is important that this component be fused into strongly bound clusters (via a thermal, chemical or electrochemical process) since this bonding likely imparts good electrical contact between nanoparticles. It should be noted that in embodiments of the invention, step 202 may be performed before step 201.

In process 203, a dispersant and/or a flocculant may be added to aqueous slurry solution 30 for rheological control. Examples of flocculants include, but are not limited to, Triton X-100 (C14H22O(C2H4O)n), carboxylic acids such as trimesic acid and the like. These flocculants increase the viscosity of the titanium dioxide slurry solution. Dispersants may include acetyl acetone and carboxylic acids, such as acetic acid and benzoic acid and the like. The flocculants and dispersants aid in the coalescence of interconnected networks by sterically guiding their assembly, and facilitate control of coating thickness of a titanium dioxide film while imparting good mechanical and aesthetic properties to the films. Significantly, unlike in traditional sintered films, the flocculant and dispersant molecules are not removed by thermal treatment and thus remain in the completed dye-sensitized solar cell.

In process 204, one or more other metal oxides may be added to slurry solution 30. For example the additional metal oxide may include TiO₂ having mean diameter of approximately 20-50 nm. TiO₂ having mean diameter of approximately 20-50 nm is expected to enhance adsorption of light by acting as mirrors by a photonics effect. Further, TiO₂ having mean diameter of approximately 20-50 nm or other metal oxides may enhance light scattering, and/or high surface area particles for enhanced dye adsorption. Process 204 may also include adding TiO₂ having mean diameter of approximately 450-1000 nm, added as powder at 10 wt % of slurry solution 30. TiO₂ having mean diameter of approximately 450-1000 nm is non conductive and gives the titanium dioxide film occlusion properties.

Slurry solution 30 may be agitated in process 205 by known methods such as by air or by stirring mechanically. In process 206, aqueous slurry solution 30 is placed on anode 35 to form film 36 (FIG. 3B). Anode 35 may be made of material such as copper, nickel, aluminum, silver, conductive polymer, carbon, carbon nanotubes, graphene, the like and combinations thereof. Significantly, the anode material is not limited by a need to have it being able to withstand a sintering process. FIG. 3B shows that good contact amongst particles 31 and 32 and anode 35 is achieved. In embodiments of the invention, after process 202, which involves the adding of fused titanium dioxide nanoparticles 32 to the solvent, process 30 may skip one or more of processes 203 to 205 and proceed to process 206 which involves depositing slurry solution 30 on anode 35.

Titanium dioxide nanoparticle aggregate 31 act as flocculants to titanium dioxide nanoparticles 32 and titanium dioxide nanoparticle agglomerate 34. The use of nanoparticles as flocculants is a well known rheological method as disclosed in the Encyclopedia of Surface and Colloid Science. This rheological method may be used to achieve a titanium dioxide film with large surface area without the disadvantages of sintering. Without being bound by any theory offered herein, it is believed that one property of titanium dioxide nanoparticle aggregate 31 that make it amenable to use in the present disclosure is the loose bonding of the nanoparticles. These loose bonds may be broken by agitation to create a dispersible solution. It is believed that this liberation of individual or small clusters of nanoparticles is a significant aspect to the present embodiment of the invention for several reasons.

For example, due to the large surface charge/size ratio of titanium dioxide nanoparticle aggregate 31, they act as an aggregating agent to the larger titanium nanoparticles 32 and titanium dioxide nanoparticle agglomerate 34. Further, the “bimodal” nature of the particle size distribution in the present embodiment of the invention leads to better packing of particles within titanium dioxide film 36 and hence, better electrical contact between titanium dioxide nanoparticle aggregate 31 and titanium dioxide nanoparticle agglomerate 34 and keeps electrolyte used in the dye-sensitized solar cell away from anode 35. Both effects are beneficial for dye-sensitized solar cell performance. Furthermore, better packing provides a more complete barrier surface on the anode. This barrier is thought to be important in preventing reduction of the electrolyte at the anode rather than at the cathode. The flocculation of titanium dioxide nanoparticles 32 and titanium dioxide nanoparticle agglomerate 34 by titanium dioxide nanoparticle aggregate 31 creates, upon drying, titanium dioxide film 36, which is a continuous conducting network of titanium dioxide nanoparticles.

Process 207 involves the removal of the solvent from the aqueous solution by, for example, the application of heat. In embodiments of the invention, anode 35 and titanium dioxide film 36 are heated to a temperature of about 75° C. until titanium dioxide film 36 is sufficiently dry. Significantly, there is no need to expose titanium dioxide film 36 to sintering temperatures of 300-500° C. as practiced in other methods. Indeed, embodiments of the invention may be practiced by exposing titanium dioxide films to temperatures of up to 150° C. and in some embodiments up to 200° C. Drying at low temperatures improves the interconnectivity of the particles within the thin film prepared using aqueous slurry solution 30, by allowing time for rearranging (“coalescing”) into arrangements having more efficient packing.

Titanium dioxide film 36 requires no further heat treatment prior to the adsorption of light sensitive dye in process 208. Appropriate light sensitive dyes for use in the embodiments of the invention disclosed herein may include, but are not limited to, organometallic and/or organic dyes including ruthenium bipyridyl dicarboxylate dye (N3), other chromophores containing carboxylic acids or functional groups capable of adsorption to and or bonding with titanium dioxide, the like and combinations thereof. Once titanium dioxide film 36 is prepared it may be used to produce a dye-sensitized solar cell. Dye-sensitized solar cells produced using films prepared by embodiments of the invention demonstrated efficiencies comparable to those seen in standard high temperature prepared dye-sensitized solar cells.

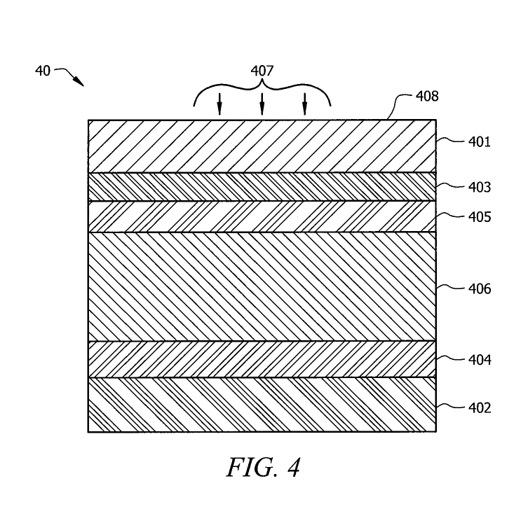

FIG. 4 is a cross-sectional view of dye-sensitized solar cell 40 of an exemplary embodiment of the invention. The components of solar cell 40 may be stacked, or vertically oriented, to accept incident light 407 at top surface 408. Solar cell 40 of the illustrated embodiment includes anode 403, semiconductor 405 coated with a photo-sensitive dye, electrolyte 406, cathode 404, superstrate 401, and substrate 402. In the illustrated embodiment, anode 403 is interfaced with semiconductor 405 and superstrate 401; semiconductor 405 is interfaced with electrolyte 406; electrolyte 406 is interfaced with cathode 404; and cathode 404 is interfaced with substrate 402. Components of solar cell 40 are not drawn to scale and are not intended to show relative dimensions of each layer.

In various embodiments, superstrate 401 may be clear or transparent to allow light to pass through and may include one or more of the following materials: poly (methyl methacrylate) (also called PMMA) and poly(ethylene terephthalate) (also called PET). Substrate 402 may include, for example, PET. Further, anode 403 and cathode 404 may be made of material such as copper, nickel, aluminum, silver, conductive polymer, carbon, carbon nanotubes, graphene, the like and combinations thereof. Exemplary materials providing functionality of the photo-sensitive dye include, but are not limited to, organometallic and/or organic dyes including ruthenium bipyridyl dicarboxylate dye (N3), other chromophores containing carboxylic acids or similar functional groups, the like and combinations thereof.

Further, in various embodiments, semiconductor 405 may be selected from a variety of compounds, including a single, a binary, a ternary, or a quaternary metal oxide compound and combinations thereof. Exemplary metal oxide compounds include barium titanate, calcium titanate, hafnium oxides, magnesium oxides, manganese oxides, tin oxides, titanium oxides (e.g., titanium dioxide), zinc oxides, zirconium oxides and combinations thereof. Other oxide compounds, such as hydroxyapatite and silicon oxides, may also be used. Typically, however, semiconductor 405 includes titanium dioxide. The aforementioned oxide compounds may be incorporated into a semiconductor in various forms, including in the form or nanopowders or nanoparticles. Further, photo-sensitive dye of semiconductor 405 may be impregnated or adsorbed on the semiconductor material. The photo-sensitive dye may include, but is not limited to, organometallic and/or organic dyes including ruthenium bipyridyl dicarboxylate dye (N3), other chromophores containing carboxylic acids or functional groups capable of adsorption to and or bonding with titanium dioxide, the like and combinations thereof. In some embodiments, electrolyte 406 may be iodide/triiodide.

Provided below is an example of tests carried out to show the results of embodiments of the present disclosure.

### Example

### Performance of Photovoltaic Devices Prepared Using the Low Temperature Films

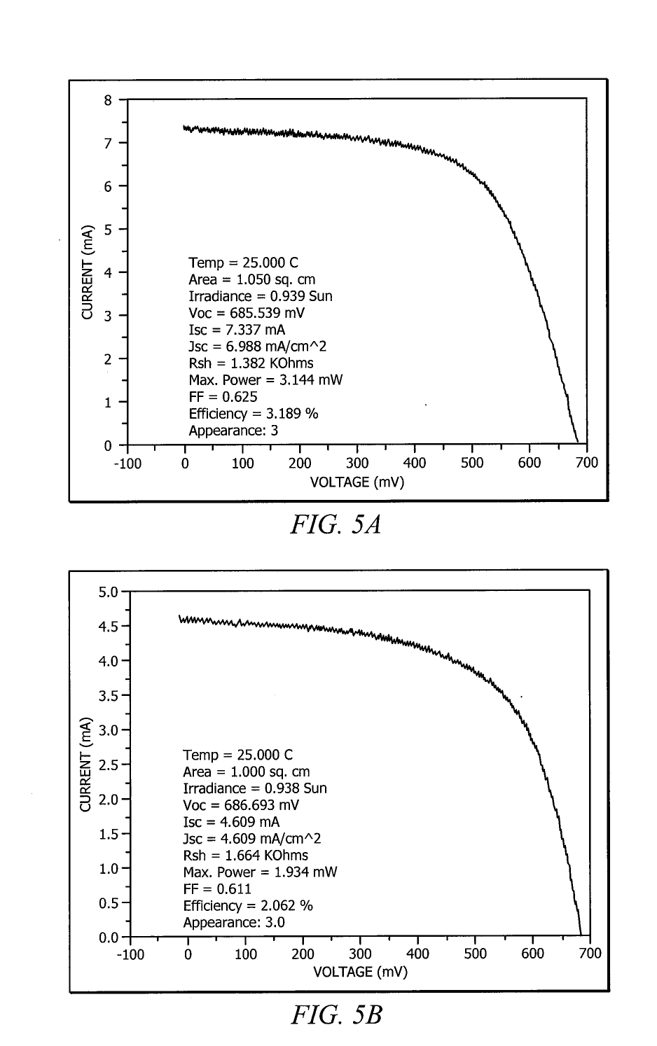

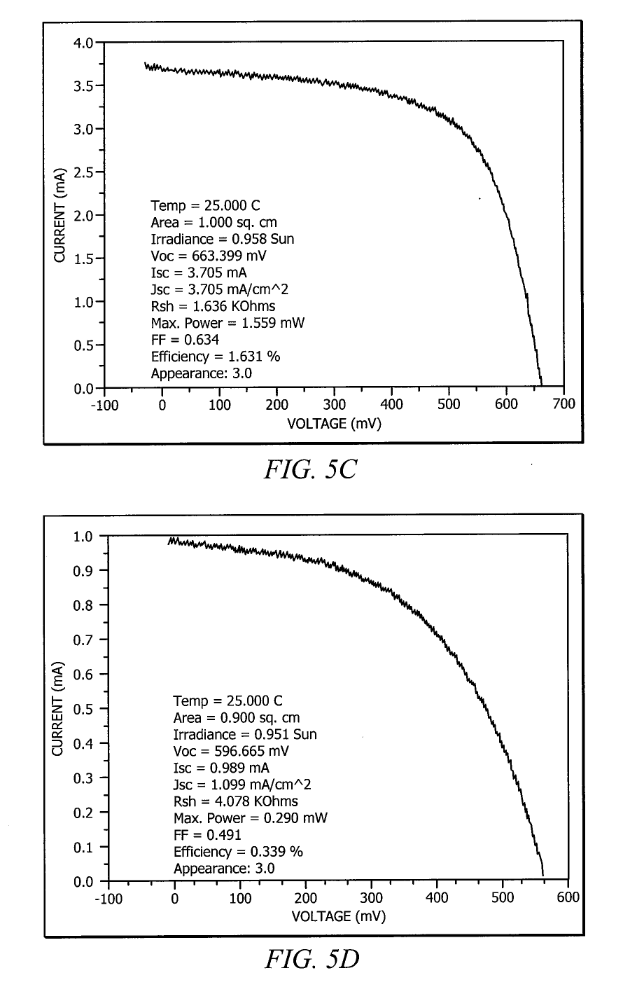

Titanium dioxide slurry (referred to herein as WBI PM10) was prepared as described in process 20. Three WBI PM10 coatings were deposited on conductive glass substrate by doctor-blading method. One coating was sintered at 450° C., the second coating was heated to 75° C., and the third coating remained at room temperature. In addition, titanium dioxide slurry (further referred to as WBI P25), which did not contain dispersed nanoparticles prepared by sol-gel method, was prepared to include the following components: Degussa P25 titanium dioxide, acetyl acetone, Triton-X100, and STREM TiO₂ micron sized particles. See Cannon. WBI P25 coating was deposited on conductive glass by doctor-blading method and heated to 100° C. Subsequently ruthenium polypyridyl dye (N3 dye) was adsorbed on each of the coatings and four dye-sensitized solar cells were assembled. The current-voltage characteristics of the assembled dye-sensitized solar cells are presented in FIGS. 5A-5D.

FIGS. 5A-5D show characteristics and performance parameters of the dye-sensitized solar cells with titanium dioxide film prepared from WBI PM10 slurry, sintered at 450° C. (FIG. 5A); WBI PM10 slurry, dried at 75° C. (FIG. 5B); WBI PM10 slurry, dried at room temperature (FIG. 5C); WBI P25 slurry, dried at 100° C. (FIG. 5D). This performance data of the dye-sensitized solar cells is summarized in Table 1 below.

TABLE 1

| | | Heat | | | | |
|---|---|---|---|---|---|---|
| TiO₂ | | treatment | V_{OC} | J_{SC} | Fill | |
| slurry | Cell # | temperature | mV | mA/cm² | Factor | Efficiency |
| WBI | WBI023- | 450° C. | 686 | 7.0 | 0.625 | 3.2% |
| PM10 | 143-PM9 | | | | | |
| WBI | WBI023- | 75° C. | 687 | 4.6 | 0.611 | 2.1% |
| PM10 | 143-PM10 | | | | | |
| WBI | WBI023- | Room | 663 | 3.7 | 0.634 | 1.6% |
| PM10 | 147-LT2 | temperature | | | | |
| WBI | WBI023- | 100° C. | 597 | 1.1 | 0.491 | 0.3% |
| P25 | 134-P3 | | | | | |

It is clear from the data in Table 1 that the addition of dispersed titanium dioxide nanoparticles significantly improves performance of the dye-sensitized solar cells prepared with nonsintered titanium dioxide films.

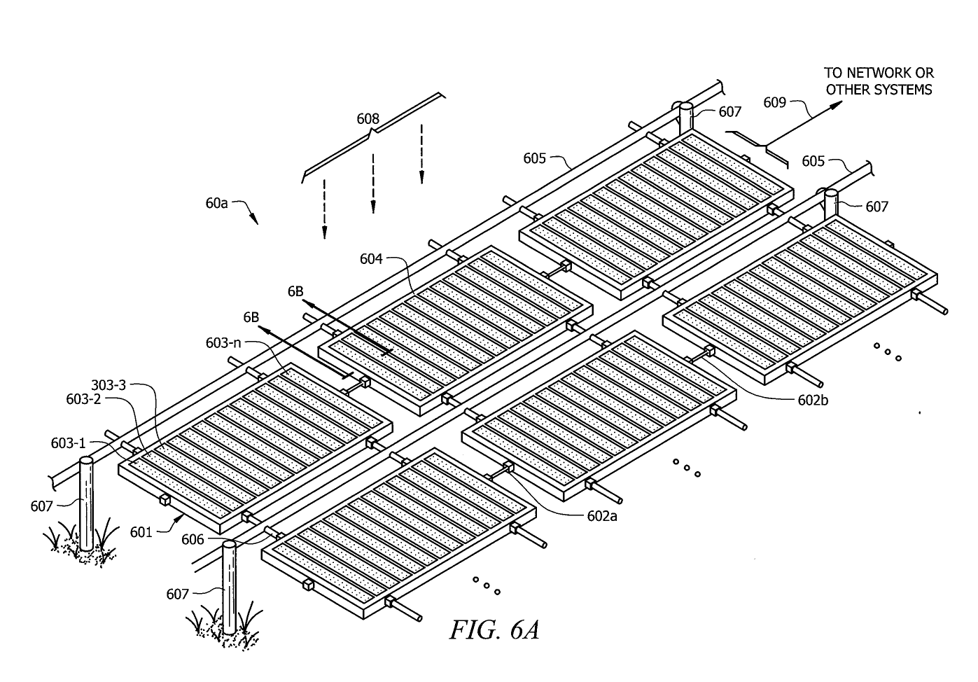

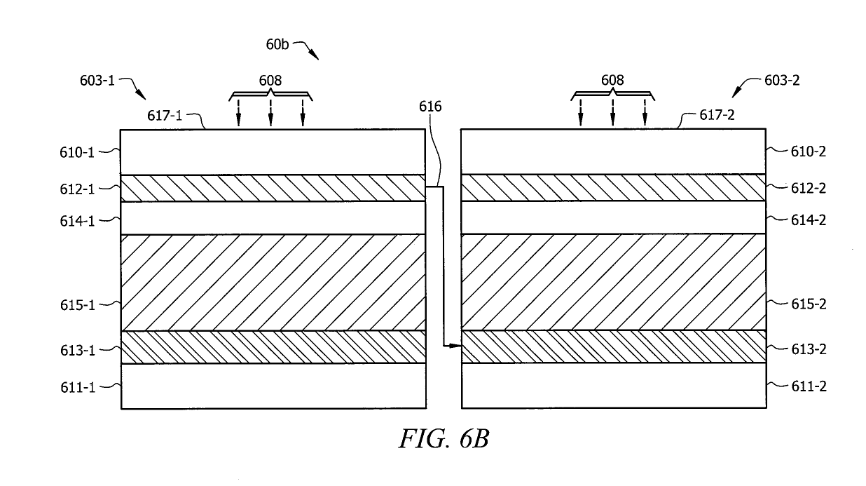

FIG. 6A illustrates an exemplary embodiment of a solar panel support structure 60a. In the exemplary embodiment illustrated in FIG. 6A, array of modules 601, including plurality of solar cells 603-1 to 603-n, are held in position to receive incident light 608 by support structure 60a. In this embodiment, support structure 60a includes tensioned wires or support cables 605. Support cables 605 may, as illustrated, run coextensive with the horizontal plane (i.e., module surfaces 604) of modules 601. Support cables 605 are supported by posts 607. Posts 607 and support cables 605 also provide elevation to array of modules 601. Further, modules 601 are connected to support cables 605 by one or more support connectors 606.

FIGS. 6A and 6B illustrate an exemplary embodiment of the flow of electricity between modules and solar cells, respectively. In the embodiment illustrated in FIG. 6A, modules 601 are connected in series such that the output of one module 601 is the input of an adjacent module via electrical connectors 602a and electrical cables 602b. Electrical energy produced at modules 601 follows path 609 for collection and/or distribution to a structure, network, or other system. In the embodiment illustrated in FIG. 6B, the flow of electricity within module 601 and among solar cells 603-1 to 603-n is shown. Depicted is a cross-sectional view 60b of neighboring solar cells 603-1 and 603-2 receiving incident light 608 at solar cell surfaces 617-1 and 617-2, respectively. Solar cells 603-1 and 603-2 each respectively include superstrates 610-1 and 610-2, anodes 612-1 and 612-2, semiconductors 614-1 and 614-2, electrolytes 615-1 and 615-2, cathodes 613-1 and 613-2, and substrates 611-1 and 611-2. Electrical path 616 demonstrates the flow of electrical energy from anode 612-1 of solar cell 603-1 to cathode 613-2 of solar cell 603-2. This transfer of electricity continues to the next solar cell of module 601 until reaching solar cell 603-n, and then exiting the module via electrical connector 602a and electrical cable 602b (illustrated in FIG. 6A).

Although a preferred embodiment of the present invention has been described with reference to the steps of FIG. 2, it should be appreciated that operation of the present invention is not limited to the particular steps and/or the particular order of the steps illustrated in FIG. 2. Accordingly, alternative embodiments may provide functionality as described herein using various steps in a sequence different than that of FIG. 2. Any order of implementing steps 201-208 may be used in embodiments of the invention.

Although the present invention and its advantages have been described in detail, it should be understood that various changes, substitutions and alterations can be made herein without departing from the spirit and scope of the invention as defined by the appended claims. Moreover, the scope of the present application is not intended to be limited to the particular embodiments of the process, machine, manufacture, composition of matter, means, methods and steps described in the specification. As one of ordinary skill in the art will readily appreciate from the disclosure of the present invention, processes, machines, manufacture, compositions of matter, means, methods, or steps, presently existing or later to be developed that perform substantially the same function or achieve substantially the same result as the corresponding embodiments described herein may be utilized according to the present invention. Accordingly, the appended claims are intended to include within their scope such processes, machines, manufacture, compositions of matter, means, methods, or steps.

What is claimed is:

1. A method comprising:
flocculating a metal oxide solution; and
processing said flocculated metal oxide solution to form a component for use in a solar cell, wherein said processing does not involve sintering.

2. The method of claim 1 wherein said metal oxide solution comprises a first set of titanium dioxide particles and said flocculating is promoted by mixing a flocculating agent with said metal oxide solution.

3. The method of claim 2 wherein said flocculating agent comprises a second set of titanium dioxide particles that are smaller than said first set of titanium dioxide particles.

4. The method of claim 3 wherein said flocculating agent further comprises a selection from the list consisting of: C₁₄H₂₂O(C₂H₄O)ₙ, trimesic acid, carboxylic acid and combinations thereof.

5. The method of claim 2 wherein said first set of titanium dioxide particles comprises titanium dioxide nanoparticles having a mean crystal diameter of 5-10 nm and aggregate dimension of 95-105 nm and said second set of titanium dioxide particles comprises fused metal oxide nanoparticles having a mean crystal diameter of 10-20 nm and agglomerate dimension of 425-475 nm clusters.

6. The method of claim 5 further comprising:
adding titanium dioxide particles having mean crystal diameter of 20-50 nm to said metal oxide solution.

7. The method of claim 5 further comprising:
adding titanium dioxide particles having mean crystal diameter of 450-1000 nm to said metal oxide solution.

8. The method of claim 1 wherein said processing further comprises adding a dispersant selected from the list consisting of: acetyl acetone and carboxylic acids such as acetic acid and benzoic acid and combinations thereof.

9. The method of claim 1 wherein said processing comprises:
depositing said flocculated metal oxide solution on a substrate; and
heating said flocculated metal oxide solution at a temperature of 70-100° C. to form a film.

10. The method of claim 1 wherein said processing further comprises coating said metal oxide film with a light sensitive dye.

11. The method of claim 1 wherein said metal oxide is selected from the list consisting of: single, binary, ternary, and quaternary metal oxide compounds, aluminum oxides, barium titanate, calcium titanate, hafnium oxides, magnesium oxides, manganese oxides, tin oxides, titanium oxides, zinc oxides, and zirconium oxides and combinations thereof.

12. A method of making a component for use in a solar cell, said method comprising:
forming an aqueous solution by a process that comprises:
adding titanium dioxide nanoparticles having a mean crystal diameter of 5-10 nm and aggregate dimension of 95-105 nm to a solvent;
adding fused titanium dioxide nanoparticles having a mean crystal diameter of 10-20 nm and agglomerate dimension of 425-475 nm clusters to said solvent;
agitating said aqueous solution; and
removing at least some of said solvent from said aqueous solution to produce a metal oxide film, wherein said metal oxide film is not sintered.

13. The method of claim 12 further comprising:
adding titanium dioxide particles having mean crystal diameter of 20-50 nm to said solvent.

14. The method of claim 12 further comprising:
adding titanium dioxide particles having mean crystal diameter of 450-1000 nm to said solvent.

15. The method of claim 12 wherein said forming further comprises:
adding a flocculant to said solvent, wherein said flocculant comprises material selected from the list consisting of: C₁₄H₂₂O(C₂H₄O)ₙ, trimesic acid, carboxylic acid and combinations thereof.

16. The method of claim 12 wherein said forming further comprises:
adding a dispersant to said solvent, wherein said dispersant is selected from the list consisting of: acetyl acetone and carboxylic acids such as acetic acid and benzoic acid and combinations thereof.

17. The method of claim 12 wherein said forming further comprises:
adding TiO₂ to said solvent.

18. The method of claim 17 wherein said aqueous solution comprises 10 wt % of said TiO₂ after said adding steps.

19. The method of claim 12 wherein said removing of said solvent comprises:
depositing said aqueous solution on a substrate; and
heating said aqueous solution at a temperature of 70-100° C.

20. The method of claim 12 wherein said aqueous solution comprises 5-15 wt % of said metal oxide nanoparticles having a mean crystal diameter of 5-10 nm and aggregate dimension of 95-105 nm, after said adding steps.

21. The method of claim 12 wherein said aqueous solution comprises 20-50 wt % of said fused metal oxide nanoparticles having a mean crystal diameter of 10-20 nm and agglomerate dimension of 425-475 nm clusters, after said adding steps.

22. A solar cell component comprising a metal oxide that is produced by a method that does not require sintering of said metal oxide, said method comprising:
flocculating a solution of said metal oxide; and
processing said flocculated metal oxide solution to form said solar cell component.

23. The solar cell component of claim 22 wherein said metal oxide solution comprises a first set of titanium dioxide particles and said flocculating is promoted by mixing a flocculating agent with said metal oxide solution.

24. The solar cell component of claim 23 wherein said flocculating agent comprises a second set of titanium dioxide particles that are smaller than said first set of titanium dioxide particles.

25. The solar cell component of claim 23 wherein said first set of titanium dioxide particles comprises titanium dioxide nanoparticles having a mean crystal diameter of 5-10 nm and aggregate dimension of 95-105 nm and said second set of titanium dioxide particles comprises fused metal oxide nanoparticles having a mean crystal diameter of 10-20 nm and agglomerate dimension of 425-475 nm clusters.

26. The solar cell of claim 25 further comprising:
adding titanium dioxide particles having mean crystal diameter of 20-50 nm to said metal oxide solution.

27. The method of claim 25 further comprising:
adding titanium dioxide particles having mean crystal diameter of 450-1000 nm to said metal oxide solution.

28. The solar cell component of claim 22 wherein said processing comprises:
depositing said flocculated metal oxide solution on a substrate; and
heating said flocculated metal oxide solution at a temperature of 70-100° C. to form a film.

29. The solar cell component of claim 28 further comprising:
a light sensitive dye.

30. A non-sintered solar cell component comprising:
metal oxide nanoparticles having a mean crystal diameter of 5-10 nm and aggregate dimension of 95-105 nm; and
fused metal oxide nanoparticles having a mean crystal diameter of 10-20 nm and agglomerate dimension of 425-475 nm clusters.

31. The solar cell component of claim 30 wherein said metal oxide comprises titanium dioxide.

32. The solar cell component of claim 30 wherein said metal oxide is selected from the list consisting of: single, binary, ternary, and quaternary metal oxide compounds, aluminum oxides, barium titanate, calcium titanate, hafnium oxides, magnesium oxides, manganese oxides, tin oxides, titanium oxides, zinc oxides, and zirconium oxides and combinations thereof.

33. The solar cell component of claim 30 further comprising:
titanium dioxide particles having mean crystal diameter of 20-50 nm.

34. The solar cell component of claim 30 further comprising:
titanium dioxide particles having mean crystal diameter of 450-1000 nm.

35. The solar cell component of claim 30 further comprising:
a light sensitive dye.

36. The solar cell component of claim 30 further comprising:
a flocculant comprising material selected from the list consisting of: C₁₄H₂₂O(C₂H₄O)ₙ, trimesic acid, carboxylic acid and combinations thereof.

37. The solar cell component of claim 30 further comprising:
a dispersant selected from the list consisting of: acetyl acetone and carboxylic acids such as acetic acid and benzoic acid and combinations thereof.

38. A composition for use in making a non-sintered solar cell component, said composition comprising:
a metal oxide solution; and
a flocculant for flocculating particles of said metal oxide solution.

39. The composition of claim 38 wherein said metal oxide solution comprises a first set of titanium dioxide particles.

40. The composition of claim 39 wherein said flocculant comprises a second set of titanium dioxide particles that are smaller than said first set of titanium dioxide particles.

41. The composition of claim 39 wherein said first set of titanium dioxide particles comprises titanium dioxide nanoparticles having a mean crystal diameter of 5-10 nm and aggregate dimension of 95-105 nm and said second set of titanium dioxide particles comprises fused metal oxide nanoparticles having a mean crystal diameter of 10-20 nm and agglomerate dimension of 425-475 nm clusters.

42. The composition of claim 41 wherein said first set of titanium dioxide particles, having a mean crystal diameter of 5-10 nm and aggregate dimension of 95-105 nm, comprises 5-15 wt % of said composition.

43. The composition of claim 41 wherein said second set of titanium dioxide particles comprising fused metal oxide nanoparticles, having a mean crystal diameter of 10-20 nm and agglomerate dimension of 425-475 nm clusters, comprises 20-50 wt % of said composition.

44. The composition of claim 41 further comprising:
titanium dioxide particles having mean crystal diameter of 20-50 nm.

45. The composition of claim 41 further comprising:
titanium dioxide particles having mean crystal diameter of 450-1000 nm.

46. The composition of claim 41 wherein said flocculant comprises material selected from the list consisting of: C₁₄H₂₂O(C₂H₄O)ₙ, trimesic acid, carboxylic acid and combinations thereof.

47. The composition of claim 38 further comprising:
a dispersant selected from the list consisting of: acetyl acetone and carboxylic acids such as acetic acid and benzoic acid and combinations thereof.

48. The composition of claim 38 wherein said metal oxide is selected from the list consisting of: single, binary, ternary, and quaternary metal oxide compounds, aluminum oxides, barium titanate, calcium titanate, hafnium oxides, magnesium oxides, manganese oxides, tin oxides, titanium oxides, zinc oxides, and zirconium oxides and combinations thereof.

49. A solar cell comprising:
an anode;
interfacing said anode, a semiconductor that comprises a metal oxide that is produced by a method that does not require sintering of said metal oxide, said method comprising:
flocculating a solution of said metal oxide; and
processing said flocculated metal oxide solution to form said semiconductor;
a cathode; and
an electrolyte in electrical communication with said semiconductor and said cathode.

50. The solar cell of claim 49 wherein said metal oxide solution comprises a first set of titanium dioxide particles and said flocculating is promoted by mixing a flocculating agent with said metal oxide solution.

51. The solar cell of claim 50 wherein said flocculating agent comprises a second set of titanium dioxide particles that are smaller than said first set of titanium dioxide particles.

52. The solar cell of claim 51 wherein said first set of titanium dioxide particles comprises titanium dioxide nanoparticles having a mean crystal diameter of 5-10 nm and aggregate dimension of 95-105 nm and said second set of titanium dioxide particles comprises fused metal oxide nanoparticles having a mean crystal diameter of 10-20 nm and agglomerate dimension of 425-475 nm clusters.

53. The solar cell of claim 49 wherein said semiconductor comprises a light sensitive dye.
